(19) United States
(12) Patent Application Publication
(10) Pub. No.: US 2005/0179088 A1
(43) Pub. Date: Aug. 18, 2005

(54) ESD protective apparatus for a semiconductor circuit having an ESD protective circuit which makes contact with a substrate or guard ring contact

(75) Inventors: Ulrich Glaser, Munchen (DE); Harald Gossner, Rlemerling (DE); Jens Schneider, Munchen (DE); Martin Streibl, Petershausen (DE); Silke Bargstadt-Franke, Munchen (DE)

Correspondence Address: BRINKS HOFER GILSON & LIONE, P.O. BOX 10395, CHICAGO, IL, 60610, US

(73) Assignee: Infineon Technologies AG

(21) Appl. No.: 11/059,778

(22) Filed: Feb. 16, 2005

(30) Foreign Application Priority Data
Feb. 17, 2004 (DE) DE 10 2004 007 65

(51) Int. Cl. H01L 23/62

(52) U.S. Cl. 257/356

(57) ABSTRACT

An electrostatic discharge (ESD) protective apparatus for a semiconductor circuit has at least one ESD protective element, which is connected between the substrate contact and a ground potential connection, and is electrically connected to the substrate contact. The ESD protective element may be in the form of an ESD protective diode or an ESD protective transistor. It is also possible to connect a resistor or an ESD protective transistor between the substrate contact and the ground potential connection as an ESD protective element, and additionally to connect an ESD protective diode or an ESD protective transistor between the substrate contact and a supply voltage potential connection.

### PRIORITY

This application claims the benefit of priority to German Patent Application, filed on Feb. 17, 2004, herein incorporated by reference in its entirety.

### TECHNICAL FIELD

This application relates to an electrostatic discharge (ESD) protective apparatus for a semiconductor, in particular an integrated circuit.

### BACKGROUND

Integrated circuits (ICs) can suffer serious damage or can be destroyed as a consequence of electrostatic discharge (ESD) events. The electrical charge associated with a discharge can be produced in many ways, for example by a lightning strike, friction between insulating bodies, as is the case with synthetic fiber cladding, or by contact with an automatic chip handling apparatus. Damage or destruction can occur whenever the ESD voltage is coupled, for example, to one or more of the I/O connections (signal inputs and outputs of an integrated circuit) or voltage connections, or is present there.

It is also possible, as a result of voltage differences during an ESD discharge between doping regions such as n wells which are connected to different supply voltages, for electrical flashovers to occur at these points. As long as the current in these situations remains limited to a value below a specific threshold, this process is reversible and no destruction occurs. This is ensured in particular in the case of a high-impedance flashover characteristic, which can be observed at points such as these up to a specific current level. However, if the current densities during this flashover are higher, a low-impedance response occurs as a result of the triggering of a parasitic bipolar transistor, as a result of which the current rises sharply, which can result in local melting and thus in irreversible destruction. One typical measure at critical points such as these is to ensure by choice of a suitable separation between the n well areas that it is impossible for the parasitic transistor to break down as a result, for example, of so-called punch-through effects or other breakdown effects. However, this (destructive) low-impedance state can occur not only as a result of these mechanisms but also by the drive level of the parasitic bipolar transistor being increased, for example by the local substrate potential being changed by the potential distribution when an ESD event occurs. With normal ESD protective concepts, the supply voltage networks (VDD networks), cannot be protected directly, that is to say via back-to-back parallel-connected diodes or a double bond with respect to one another, for example because the operating voltages are different. In consequence, the ESD pulse is dissipated via the ground potential rail (VSS rail) where significant voltage drops occur. If substrate contacts are connected to this VSS network, these voltage drops can lead to the drive level mentioned above.

The semiconductor circuits or in integrated circuits are provided with ESD protective apparatuses in order to protect them against such overvoltages and against damage and destruction resulting from them. In modern integrated circuits, these circuits have ESD resistance for voltages up to several kV, and currents up to the order of magnitude of several A. Therefore, voltage drops between the voltage connections or on the bus lines are avoided, and the impedance of the bus lines are kept low. In this context, the expression bus lines also mean voltage supply rails.

One known ESD protective apparatus is disclosed in the German Laid-Open Specification DE 199 44 489 A1, which describes an ESD protective apparatus for signal inputs and outputs for semiconductor apparatuses, in which a semiconductor substrate is connected to a substrate bus for application of a ground substrate potential to the semiconductor substrate, and a semiconductor doping zone in the semiconductor substrate is connected to a power bus in order to apply a ground power potential to the semiconductor doping zone, with a parasitic diode being formed between the power bus and the substrate bus. A supply voltage potential can be supplied via a supply bus to the semiconductor apparatuses, which are provided with I/O pads. Furthermore, in the case of the known ESD protective arrangement, a forward-biased avalanche diode is connected between the substrate bus and the supply bus, and an additional forward-biased ESD diode is connected between the power bus and the supply bus. The known ESD protective apparatus offers protection against damage resulting from an ESD load on the substrate bus and on the power bus, that is to say on the two ground buses. During normal operation, these buses are at the same potential. The Laid-Open Specification discloses an ESD concept for protection between the buses in the I/O supply network, that is to say only for the signal inputs and outputs. However, the known ESD protective apparatus is not suitable and is also not designed for providing reliable protection in order to avoid damage or destruction of the substrate contents, well contacts or guard ring contacts, their electrical supply line or the doping zones in the core area of a semiconductor circuit when an ESD event occurs.

FIG. 1 shows a further known ESD protective apparatus, where a p+ doping zone (as a substrate contact) as well as two n well areas are formed in a substrate S. The p+ substrate contact is electrically connected to ground potential VSS. The first n well area makes electrical contact with a first supply voltage potential VDDP, and the second n well area makes electrical contact with a second supply voltage potential VDD. A first parasitic bus resistance R1 and a parallel circuit comprising a first ESD protective element ESD1 and a parasitic or explicitly existing diode D1 are connected in series between the ground potential connection VSS and the first supply voltage potential connection VDDP. A second parasitic bus resistance R2 as well as a parallel circuit comprising a second ESD protective element ESD2 and a parasitic or explicitly provided diode D2 are likewise connected in series between the ground potential connection VSS and the second supply voltage potential connection VDD. As already mentioned above, one disadvantage of this known ESD protective apparatus is that a positive potential is produced locally at the ground potential connection VSS relative to the second supply voltage connection VDD owing to the dissipation of the current via the ESD protective element ESD1 and to the parasitic bus resistance R1 when an ESD event occurs at the first supply voltage potential connection VDDP. This results in the parasitic bipolar transistor possibly being driven.

In order to suppress or to inhibit the problems associated with such drives, a relatively large separation is formed between the electrodes of a parasitic bipolar transistor in order to sufficiently reduce its gain factor β. Such values for adequate separation are about 8 μm for adjacent n wells for 0.13 μm technology, by way of example, depending on the various supply voltages VDD and VDDP. This relatively large required separation considerably limits further miniaturization of a semiconductor circuit or of an integrated circuit.

A further method for prevention of driving is to connect a coupling element between the two supply voltage connections VDD and VDDP. However, these require a relatively large amount of space and are thus suitable only to a very restricted extent, on the one hand for preventing driving and furthermore to minimize the geometry of the semiconductor circuit further. In addition, the positioning and routing of these coupling elements are made considerably more difficult by the geometrically separate domains.

### BRIEF SUMMARY

An ESD protective apparatus is provided which can be designed to have little complexity and to save space and which can ensure improved ESD protection of the core area of a semiconductor circuit in terms of damage or destruction when an ESD event occurs. In particular, ESD event protection is provided for the substrate contacts, well contacts or the guard ring contacts in the core area of a semiconductor circuit.

By way of introduction only, an ESD protective apparatus is designed for a semiconductor circuit, in particular an integrated circuit. The ESD protective apparatus and the semiconductor circuit may be formed in a substrate or in an epitaxial layer. The semiconductor circuit has a first doping zone and at least two second doping zones. The first doping zone is electrically connected to at least one ground potential connection, and the second doping zones are electrically connected to supply voltage potential connections. An ESD protective circuit is connected between the first doping zone and the ground potential connection. Since at least this ESD protective circuit is connected between the first doping zone and the ground potential connection, this allows an effective and safe circuit to be designed in order to make it possible to protect the semiconductor apparatus against damage or destruction when an ESD event occurs. Particularly, but not only exclusively, when the first doping zone is arranged in the core area of the semiconductor circuit, damage is prevented to the semiconductor circuit. Furthermore, in the case of semiconductor circuits in which an ESD load can occur between two supply voltage buses, the ESD protective elements are connected in the semiconductor circuit to prevent damage in the event of ESD. Thus, when an ESD event occurs the ESD protective circuit provides blocking or represents an increased resistance when there is an increased positive voltage at the ground potential connection, thus making it possible to prevent through-connection being produced by parasitic transistors during an ESD discharge. Furthermore, the EDS protective apparatus can be produced with little complexity and in a space-saving manner so that it provides virtually no impediment, either to miniaturization of the semiconductor circuit or of an integrated circuit.

The ESD protective circuit may be designed such that the first doping zone, in particular one electrical contact of the first doping zone, has the minimum of those potentials which are present at the supply voltage potential connections and the ground potential connection. This makes it possible to provide considerably better protection for the semiconductor circuit against destruction resulting from an ESD event.

The ESD protective circuit may have at least one ESD protective diode or one ESD protective transistor. These protective elements make it possible to effectively prevent driving of the parasitic transistor, and they can be implemented in a space-saving manner. Furthermore, this allows a relatively simple layout configuration.

In a further embodiment, the anode of an ESD protective diode which may be used makes contact with the first doping zone, and its cathode is electrically connected to ground potential. Furthermore, the current path of an ESD protective transistor which may be used is connected between the first doping zone and the ground potential, and its gate connection and its substrate connection are electrically connected to the first doping zone. Circuitry such as this allows the semiconductor circuit to be effectively protected against destruction resulting from an ESD event.

The ESD protective circuit may have a first ESD protective element which is connected between a first doping zone and a ground potential connection, and a second ESD protective element which is connected between the first doping zone and one of the two supply voltage connections. It is possible to provide for the second ESD protective element to be electrically connected to that one of the two supply voltage potential connections at which the lower potential is present when a critical ESD event occurs.

A resistor, in particular a non-reactive resistor, or an ESD protective transistor can be connected as a first ESD protective element between the first doping zone and the ground potential connection as a first ESD protective element. It is also possible to provide for an ESD protective diode or an ESD protective transistor to be connected as a second ESD protective element between the first doping zone and a first or second supply voltage potential connection. This allows an ESD protective circuit which can be produced in a flexible form and which can be designed with different components to satisfy the requirements. Thus, by way of example, the first doping zone is decoupled from the ground potential connection by the resistor. It is also possible to ensure that, during normal operation, the currents, in particular the substrate currents, flow away via the resistor without any voltage drop while, in the event of ESD, the drive current is reduced and the voltage at the first doping zone, in particular at the substrate, well or guard ring contact, is clamped by an ESD protective diode. This embodiment makes possible a safe and low-complexity circuit by means of which it is possible to prevent destruction of or damage to the semiconductor circuit when an ESD event occurs. The ESD protective apparatus is physically relatively simple and can be designed quickly, thus allowing a cost-effective implementation.

It is possible to provide for the first doping zone to be in the form of a substrate and for contact to be made with it at least by a substrate contact or a guard ring contact. It is also possible to provide for the second doping zone to be in the form of well contacts. One of the two second doping zones can be electrically connected to a first supply voltage potential connection, and the other of the two second doping zones can be electrically connected to a second supply voltage potential connection.

The second ESD protective element can be electrically connected to that one of the two supply voltage potential connections at which the lower potential is present when an ESD event occurs. It is thus possible to provide optimized ESD protection for semiconductor circuits in which irreversible destruction can occur only in the event of ESD discharges in one load direction.

If the semiconductor circuit has a number of first doping zones or a number of contact points with the first doping zone or doping zones, only the first doping zones which are connected to a ground potential connection via in each case one ESD protective element may be those which are arranged adjacent to a parasitic transistor which occurs when an ESD event takes place. This makes it possible to ensure that the ESD protective apparatus is arranged only where effective ESD protection is required. This optimizes the ESD protection with respect to the minimum space requirement and allows a relatively cost-effective implementation of a semiconductor circuit, or of an integrated circuit.

It is possible to provide for a protective separation to be formed between the contacts of the first doping zone or first doping zones. Existing contacts can lead to the parasitic element being driven. Furthermore, contacts which are not located between the second doping zones (which are associated with different domains; in this case, domains are regarded as being areas with different supply voltage potentials) can likewise lead to driving when they are closer to the domain boundary than the protective separation.

The protective separation is governed by the ESD resistance of the parasitic bipolar transistor. The ESD resistance increases as the distance between the second doping zones at a domain boundary increases. If the distance or the ESD resistance, for example, is so high that any ESD pulse which occurs is dissipated via the protective elements that are provided without the parasitic elements being driven, then there is no longer any need for an ESD protective element. The ESD resistance of the parasitic element is also dependent on implantation doses and doping profiles. By restricting the installation of the additional ESD protective elements to geometric arrangements in which the minimum protective separation is not achieved, it is possible to optimize the ratio of the space required and the ESD protective elements that have to be designed. However, it should be noted that the protective separation may or may not be minimized. This separation can also be relatively large since the relevant area can be used for further structures. The existing first doping zones, with which contact is made in particular in the form of substrate, well or guard ring contacts, are protected against being damaged in the event of ESD by the ESD protective element with which contact is made in a corresponding manner.

The semiconductor circuit may have a number of first doping zones to be protected against an ESD event. Each of these first doping zones is electrically connected to a ground potential bus. This ground potential bus is electrically connected to at least one ground potential pad via an ESD protective element, in particular an ESD protective diode or an ESD protective transistor. Irrespective of the number of first doping zones to be protected against an ESD event, it is thus possible to provide only as many ESD protective elements as there are electrical connections from the ground potential bus to the ground potential pads.

It is possible to provide for the ESD protective circuit to be electrically connected to at least one supply voltage potential connection. This advantageously makes it possible to produce a number of appropriate circuits which prevent the semiconductor circuit from being destroyed when an ESD event occurs by appropriate use of ESD protective elements.

The foregoing summary has been provided only by way of introduction. Nothing in this section should be taken as a limitation on the following claims, which define the scope of the invention.

### BRIEF DESCRIPTION OF THE DRAWINGS

The invention is explained in more detail below in an exemplary manner with reference to the drawings, in which:

FIG. 1 shows a schematic illustration of a known ESD protective apparatus;

FIG. 2 shows a first embodiment of an ESD protective apparatus according to the invention;

FIG. 3 shows a second embodiment of an ESD protective apparatus according to the invention;

FIG. 4 shows a third embodiment of an ESD protective apparatus according to the invention;

FIG. 5 shows a fourth embodiment of an ESD protective apparatus according to the invention;

FIG. 6 shows a fifth embodiment of an ESD protective apparatus according to the invention;

FIG. 7 shows a plan view of a detail of an ESD protective apparatus according to the invention; and

FIG. 8 shows a sixth embodiment of an ESD protective apparatus according to the invention.

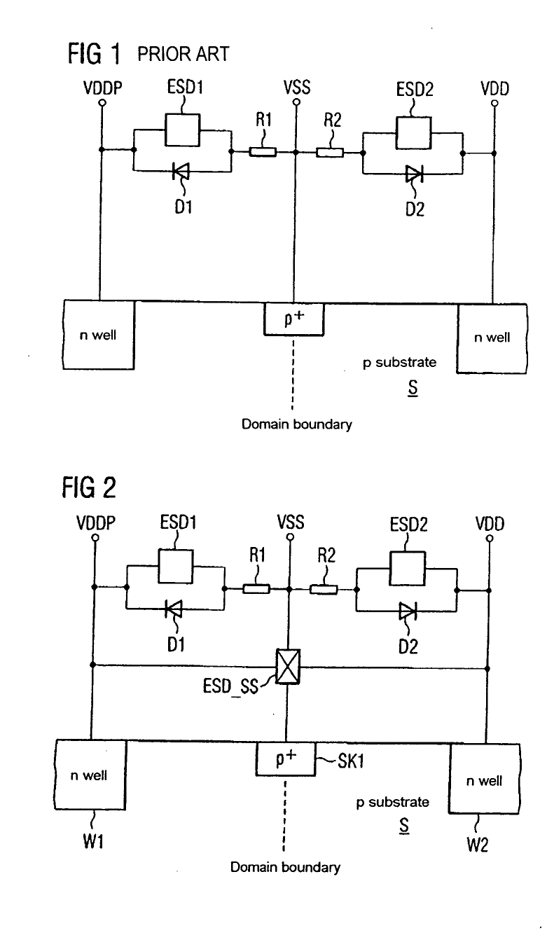

Identical or functionally identical elements are provided with the same reference symbols in the figures.

### DETAILED DESCRIPTION OF THE DRAWINGS AND THE PRESENTLY PREFERRED EMBODIMENTS

FIG. 2 shows a first embodiment of an electrostatic discharge (ESD) protective apparatus according to the invention. The simplified illustration shows those parts of a semiconductor circuit or of an integrated circuit which are essential to the explanation of the invention. A first well area W1 and a second well area W2 are formed as second doping zones in a p-conductive substrate S. In the embodiment, the well areas W1 and W2 are of the n-conduction type. The first n-well area W1 is electrically connected to a first supply voltage potential connection VDDP, and the second n well area W2 is electrically connected to a second supply voltage potential connection VDD. Furthermore, a first doping zone is formed as a substrate S for the semiconductor circuit, and contact is made with it by a substrate contact SK1. The substrate contact SK1 is in the form of a p+ zone in the embodiment. It is also possible to provide for the first doping zone to be in the form of a well and/or to be made contact with by guard ring contacts. A domain boundary of the semiconductor circuit is arranged in such a way that it runs through the substrate contact SK1. The substrate contact SK1 is electrically connected to a ground potential connection VSS via an ESD protective circuit ESD_SS. The ESD protective circuit ESD_SS in the embodiment is furthermore electrically connected to the first and to the second supply voltage potential connections VDDP and VDD, respectively. The intermediate connection, of an ESD protective circuit ESD_SS between the substrate contact SK1 and the ground potential connection VSS is provided at those substrate contacts which are arranged in the immediate vicinity of a possible parasitic transistor. The ESD protective element ESD_SS reduces the potential at the substrate contact SK1 to the minimum of the potentials at the connections VDD, VSS and VDDP. This suppresses the drive resulting from the increased VSS potential when an ESD event occurs, and prevents latching up during normal operation.

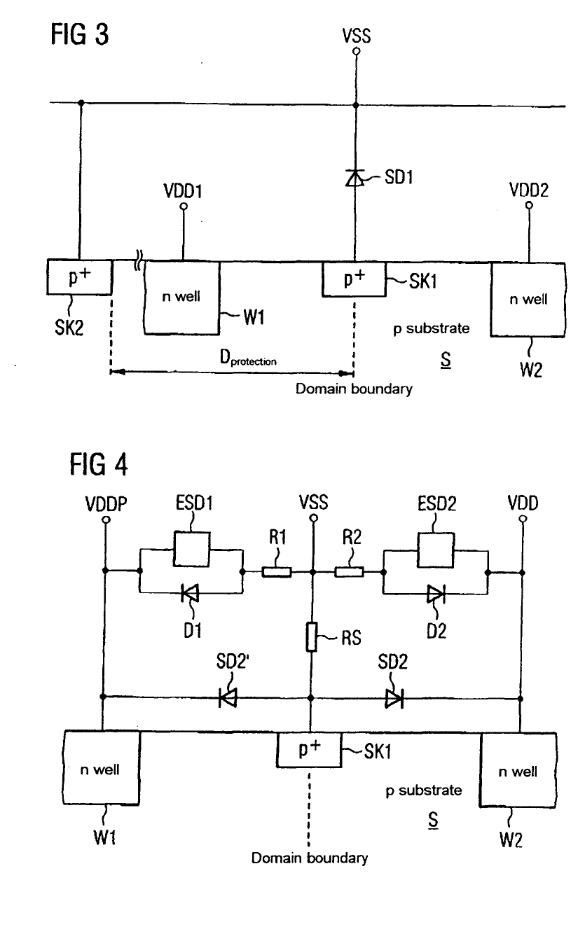

FIG. 3 shows a second embodiment of an ESD protective apparatus according to the invention. In contrast to the embodiment shown in FIG. 2, the first n well area W1 is electrically connected to a first supply voltage potential connection VDD1, and the second n well area W2 is electrically connected to a second supply voltage potential connection VDD2. The domain boundary of the semiconductor circuit is arranged such that it runs through the substrate contact SK1. A further substrate contact SK2 is formed in the substrate S with a minimum protective separation D_{protection}. It should be noted here that this is merely an illustration in the embodiment. The domain boundary may also be located at some other point, the contacts may be shifted, and further contacts may also be provided. The first substrate contact SK1 is electrically connected to the ground potential VSS via an ESD protective diode SD1 which is connected between the substrate contact SK1 and the ground potential connection VSS. The anode of the ESD protective diode SD1 is electrically connected to the substrate contact, and the cathode of the ESD protective diode SD1 is electrically connected to the ground potential network VSS. No such ESD protective diode is connected between the second substrate contact SK2 and the ground potential connection VSS.

The measure of connecting an ESD protective diode between the substrate contact SK1 and the ground potential connection VSS is carried out at those substrate contacts which are arranged in the immediate vicinity of a possible parasitic transistor. The connection of these substrate contacts SK1, which are adjacent to parasitic elements, via an ESD protective diode to ground potential networks VSS suppresses the drive resulting from the increased VSS potential when an ESD event occurs. In comparison to the prior art, this makes it possible to form the n well areas W1 and W2 considerably more closely together, thus making it possible to achieve a considerable space saving on the chip or in the integrated circuit. The anode connection of the ESD protective diode SD1 is electrically connected to the p+ substrate contact SK1, and its cathode is electrically connected to the ground potential connection VSS. During normal operation and when ESD occurs, this makes it possible for substrate currents to be dissipated via the forward-biased ESD protective diode SD1, as should be the case during normal operation. An increase in potential from the VSS network, as occurs particularly in the event of ESD, is blocked.

When ESD occurs, a voltage is produced at the substrate node which is considerably lower than that of the VSS network. The destructive sudden change in the current/voltage characteristic, that is to say the sharp rise in the current level for a specific voltage, does not occur, by virtue of the ESD protective apparatus, until considerably higher voltages between the electrodes of the parasitic transistor than is the case with the prior art. Destruction of the component in the semiconductor circuit can thus be prevented by suitable voltage clamping by appropriate ESD protective elements. The optimized arrangement of the substrate contacts SK1 and SK2 with a minimum protective separation D_{protection} also makes it possible to ensure that no space is wasted by the need for additional protective diodes, and that the distance between the well areas need not be unnecessarily increased. This allows optimum ESD protection with a minimized space requirement. However, it is also possible to provide for the substrate contacts SK1 and SK2 to be further away from one another and allows the free area to be used for further structures in the semiconductor circuit.

A third embodiment of the ESD protective device according to the invention is shown in FIG. 4. This embodiment is suitable for situations in which irreversible destruction can occur only in the event of an ESD discharge direction between the supply voltage potential connections. In the embodiment, an ESD event can occur at the first supply voltage potential connection VDDP. In this ESD protective apparatus, a non-reactive protective resistor RS is connected as an ESD protective element between the substrate contact SK1 and the ground potential connection VSS. Furthermore, an ESD protective diode SD2 is connected between the substrate contact SK1 and the second supply voltage potential connection VDD. The anode of the ESD protective diode SD2 is connected to the substrate contact SK1, and its cathode is connected to the second supply voltage potential connection VDD, so that the diode is forward-biased between the substrate contact SK1 and the VDD connection. The ESD protective diode SD2 is electrically connected to the supply voltage potential connection VDD, at which no ESD event, and thus no overvoltage, can occur in the embodiment. In the present embodiment, it may be assumed, for example, that a positive ESD pulse is applied to the first supply voltage potential connection VDDP. The ground potential connection VSS is thus effectively disconnected, and the second supply voltage potential connection VDD is at ground potential. As a result of the ESD pulse being dissipated via the ESD protective elements ESD1, ESD2, D1, D2, the additional ESD protective elements RS, SD2 and the bus resistances R1 and R2, the effectively disconnected ground potential connection VSS is at a higher potential than the connection VDD. The ESD protective diode SD2 prevents the parasitic element (parasitic transistor) from being driven and clamps the substrate contact SK1 to the connection VDD so that the maximum potential at the substrate contact SK1 is greater than the supply voltage potential VDD by a diode threshold.

The embodiment shown in FIG. 4 thus makes it possible to prevent the parasitic transistor from being driven when an ESD event occurs at VDDP, by the implementation of an ESD protective resistor RS of the order of magnitude of a few ohms, and an ESD protective diode SD2. During normal operation (without any ESD event), substrate currents flow away via the protective resistor RS with a negligible voltage drop. When an ESD event occurs, the drive current is reduced, and the voltage at the substrate or guard ring contact SK1 is clamped by the ESD protective diode SD2. The ESD protective diode SD2′ shown in FIG. 4 is not relevant to the situation being explained, and is not included.

However, analogously to the statements relating to FIG. 4, it is also possible for a situation to occur in which an ESD event occurs on VDD. In this situation, the resistor RS and the schematically indicated ESD protective diode SD2′ analogously prevent the parasitic transistor from being driven in the event of an ESD event on VDD. In this situation, the ESD protective diode SD2 is not relevant, and can be ignored.

It is also possible to provide for both the ESD protective diode SD2 and the ESD protective diode SD2′ to be implemented at the same time in an embodiment as shown in FIG. 4, and, in conjunction with the resistor RS, to also prevent the parasitic transistor from being driven when an ESD event occurs on VDDP or on VDD.

FIG. 5 shows a fourth embodiment of an ESD protective apparatus according to the invention. In contrast to the embodiment in FIG. 4, in addition to the resistor RS as a first ESD protective element for the ESD protective circuit ESD_SS, a second ESD protective transistor ST2 is provided, instead of the ESD protective diode SD2, as a second ESD protective element in the ESD protective circuit ESD_SS. The current path through the ESD protective transistor ST2 is connected between the substrate contact SK1 and the supply voltage potential connection VDD. Furthermore, the gate connection of the ESD protective transistor ST2 is electrically connected to the ground potential connection VSS and, by means of a substrate connection which may be provided, to the substrate contact SK1.

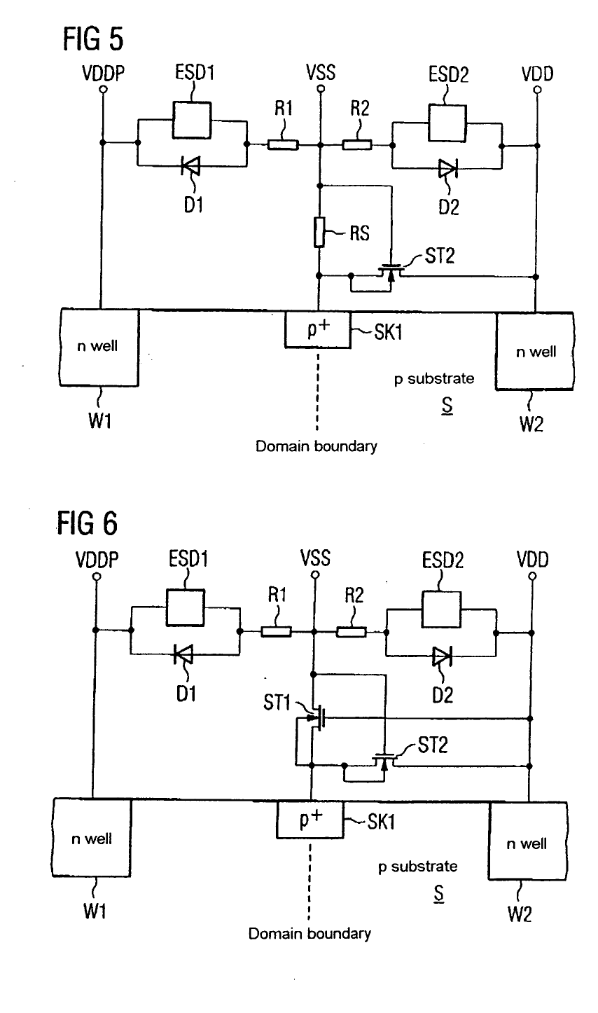

A fifth embodiment is illustrated schematically in FIG. 6. In this embodiment, both the first ESD protective element and the second ESD protective element in the ESD protective circuit ESD_SS are in the form of ESD protective transistors ST1 and ST2. The current path through the first ESD protective transistor ST1 is connected between the ground potential connection VSS and the substrate contact SK1. Furthermore, the gate connection of the first ESD protective transistor ST1 is electrically connected to the supply voltage potential VDD and, by means of a substrate connection which may be provided, to the substrate contact SK1. The second ESD protective transistor ST2 is connected to the ESD protective device in an analogous manner to the embodiment shown in FIG. 5.

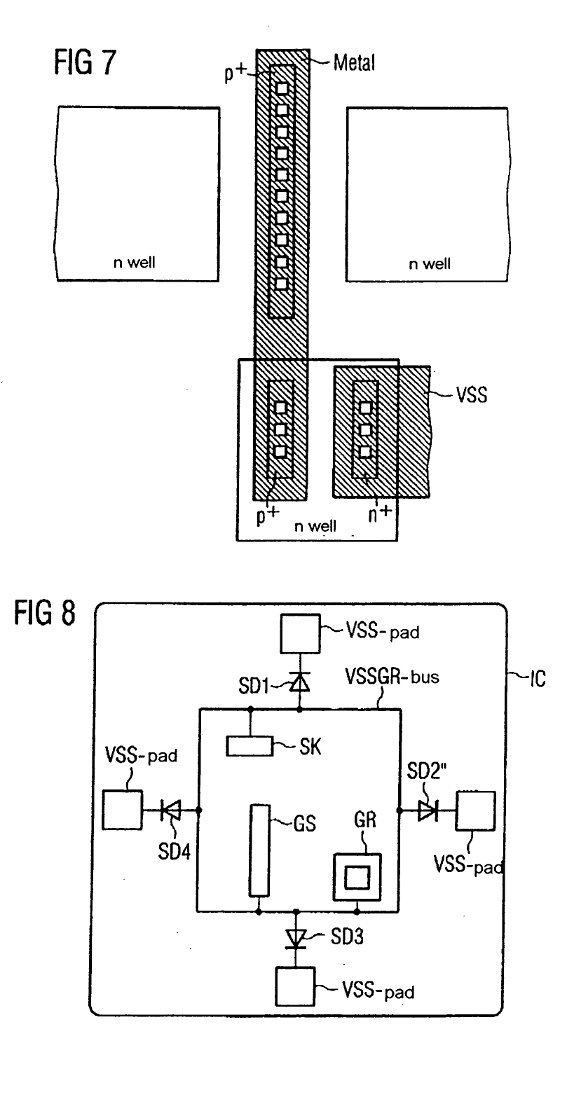

FIG. 7 shows a plan view of a partial detail of a semiconductor circuit having a number of components. This layout illustration shows schematically that each substrate contact or guard ring contact that needs to be protected is individually connected to ground potential via an ESD protective diode by means of a number of contacts, which are shown in the embodiment as being square, and metallic areas which are electrically connected to the contacts. The protective diode is shown in the lower part of the figure by the p+/n well junction. The connection via metal also symbolizes the fact that a certain separation between the substrate contact p+ and the two n wells in the upper part of the figure and the protective diode in the lower part of the figure may provide the protective effect.

FIG. 8 shows a further embodiment. An integrated circuit IC has a large number of components which are not illustrated but are formed by doping zones in the substrate. The schematic illustration shows well or substrate contacts SK, guard strips GS and guard rings GR. The substrate contacts SK, the guard strips GS and the guard rings GR are electrically connected to a ground potential bus VSSGR. This ground potential bus VSSGR is in each case electrically connected via an ESD protective diode SD1, SD2″, SD3 and SD4 to ground potential pads VSS pad, four of which are shown in the embodiment. The ESD protective diodes SD1 to SD4 are connected in the forward-biased direction between the ground potential bus VSSGR and the VSS pads. As is shown, all the substrate contacts SK, guard strips GS and guard ring contacts GR which require protection are electrically connected to the ground potential bus VSSGR. As is shown in this embodiment, the number of ESD protective diodes SD1 to SD4 is in this case dependent on the number of VSS pads which exist and make contact with the ground potential bus VSSGR. Irrespective of the number of substrate contacts SK, guard strips GS and guard rings GR which require protection against ESD events in the integrated circuit, the ESD protective diodes SD1 to SD4 have to be included. It is thus also possible to provide for the capability to connect a relatively large number of contacts SK, GS and GR that require protection to ground potential by means of a relatively small number of VSS pads and thus a small number of ESD protective diodes, thus making it possible to prevent parasitic transistors from being driven. The VSSGR bus potential is determined mainly by the very low potential on the VSS pads. If, by way of example, the potential on one VSS pad increases greatly, then that protective diode which connects this pad to the VSSGR bus becomes reverse-biased. However, the other diodes hold the bus at the lower potential of the other VSS pads plus a voltage drop across the diodes.

The embodiments shown allow effective protection in a simple and low-complexity manner against damage or destruction to components resulting from ESD events, by connecting an ESD protective circuit between a substrate, well or guard contact and a ground potential connection of a semiconductor circuit. The protective circuit may be in the form of an ESD protective diode or ESD protective transistor. In a further alternative, the ESD protective element may be formed by an ESD protective resistor and an additional ESD protective diode. However, an ESD protective circuit can also be formed in many ways from a number of components, such as ESD protective diodes and/or ESD protective transistors and/or resistors. All the alternatives can be implemented effectively, in a space-saving manner and also cost-effectively. In particular, it is possible to protect the substrate contacts, well contacts and/or guard ring contacts, their electrical supply lines and any parasitic structures which may be present in the core area of the semiconductor circuit, and thus also the core area itself, against damage or destruction resulting from an ESD event. The embodiments may be used when an ESD load occurs between two separate supply voltage buses which are at different operating voltages during normal operation and which, by virtue of this, cannot be protected directly with respect to one another, that is to say for example by back-to-back parallel-connected diodes or double bonds. The primary protection against damage in the event of an ESD load on these two supply voltage buses is ensured by the ESD protective elements which are integrated in the circuit. However, a local positive potential on the ground potential VSS with respect to the supply voltage potential VDD can lead to new ESD damage. However, this damage can once again be prevented by the ESD protective elements arranged according to the embodiments in the semiconductor circuit, in particular those ESD protective elements which make contact with the substrate contacts and are connected to ground.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

1. An electrostatic discharge (ESD) protective apparatus for a semiconductor circuit, the semiconductor circuit having a first doping zone and at least two second doping zones with the first doping zone being electrically connected to a ground potential connection and the second doping zones being electrically connected to supply voltage potential connections, the ESD protective apparatus comprising an ESD protective circuit connected between the first doping zone and the ground potential connection.

2. The ESD protective apparatus according to claim 1, wherein the ESD protective circuit is designed such that the first doping zone is at a minimum of potentials which are present at the supply voltage potential connections and at the ground potential connection.

3. The ESD protective apparatus according to claim 1, wherein the ESD protective circuit has at least one of an ESD protective diode and an ESD protective transistor.

4. The ESD protective apparatus according to claim 3, wherein:
if the ESD protective circuit has the ESD protective diode, an anode of the ESD protective diode makes contact with the first doping zone, and a cathode of the ESD protective diode is electrically connected to a ground potential, and
if the ESD protective circuit has the ESD protective transistor, a gate connection of the ESD protective transistor and a substrate connection are electrically connected to the first doping zone.

5. The ESD protective apparatus according to claim 1, wherein the ESD protective circuit is electrically connected to at least one supply voltage potential connection.

6. The ESD protective apparatus according to claim 5, wherein the ESD protective circuit has:
a first ESD protective element which is connected between a first doping zone and the ground potential connection, and
a second ESD protective element which is connected between the first doping zone and at least one of the supply voltage connections.

7. The ESD protective apparatus according to claim 6, wherein the second ESD protective element is electrically connected to the supply voltage potential connection at which the lower potential is present when an ESD event occurs.

8. The ESD protective apparatus according to claim 6, wherein at least one of a resistor and an ESD protective transistor is connected as a first ESD protective element between the first doping zone and the ground potential connection, and at least one of an ESD protective diode and an ESD protective transistor is connected as a second ESD protective element between the first doping zone and a first or second supply voltage potential connection.

9. The ESD protective apparatus according to claim 1, wherein the second doping zones are in the form of well contacts, one of the second doping zones is electrically connected to a first supply voltage potential connection and another of the second doping zones is electrically connected to a second supply voltage potential connection.

10. The ESD protective apparatus according to claim 1, wherein the semiconductor circuit has a plurality of first doping zones, and only the first doping zones arranged adjacent to a parasitic transistor are connected to the ground potential connection by an ESD protective circuit when an ESD event takes place.

11. The ESD protective apparatus according to claim 10, wherein the semiconductor circuit has a plurality of first doping zones to be protected against an ESD event, each of the first doping zones are electrically connected to a ground potential bus, and the ground potential bus is electrically connected to at least one ground potential pad via an ESD protective element.

12. The ESD protective apparatus according to claim 11, wherein the ESD protective element comprises at least one of an ESD protective diode and an ESD protective transistor.

13. The ESD protective apparatus according to claim 1, wherein the first doping zone is in the form of a substrate, and at least one substrate contact or guard ring contact makes contact with the first doping zone.
